(19) United States
(12) Patent Application Publication
(10) Pub. No.: US 2026/0103802 A1
(43) Pub. Date: Apr. 16, 2026

(54) GAS SUPPLY APPARATUS AND SUBSTRATE PROCESSING APPARATUS INCLUDING THE SAME

(71) Applicants: ACM RESEARCH (SHANGHAI), INC., Shanghai (CN); ACM Research Korea CO., LTD., Icheon-Si (KR); CleanChip Technologies Limited, Hong Kong (CN)

(72) Inventors: Shan Zhang, Shanghai (CN); Tom Kim, Icheon-Si (KR); Jacob Lee, Icheon-Si (KR); William Baek, Icheon-Si (KR); Sulan Xie, Shanghai (CN); Hongcai Fei, Shanghai (CN); Hui Wang, Shanghai (CN)

(73) Assignees: ACM RESEARCH (SHANGHAI), INC., Shanghai (CN); ACM Research Korea CO., LTD., Icheon-Si (KR); CleanChip Technologies Limited, Hong Kong (CN)

(21) Appl. No.: 19/111,693

(22) PCT Filed: Sep. 13, 2022
(86) PCT No.: PCT/CN2022/118316

§ 371 Date: Mar. 13, 2025

(51) Int. Cl. C23C 16/455

(52) U.S. Cl. CPC C23C 16/45561; C23C 16/45536

(57) ABSTRACT

A gas supply apparatus and a substrate processing apparatus including the same are provided. The gas supply apparatus supplies a plurality groups of process gas to a substrate processing apparatus of which a plurality of wafers are placed in the inside. The gas supply apparatus includes a plurality of process gas supply units configured to supply the plurality groups of process gas; a process gas temporary reservoir including an inner space partitioned into a plurality of gas storage spaces isolated from each other, each of which configured to store one group of process gas supplied from one process gas supply unit and simultaneously supply the one group of process gas to the plurality of wafers.

### BACKGROUND OF THE INVENTION

### Field of the Invention

Various embodiments may generally relate to a semiconductor device manufacturing apparatus, and more particularly to a gas supply apparatus and a substrate processing apparatus including the same.

### Description of the Related Art

In general, semiconductor devices are manufactured by repeatedly performing a series of processes, such as deposition, diffusion, and etching processes on a substrate. To manufacture the semiconductor devices, various manufacturing apparatuses may be used. As an example of a substrate processing apparatus, there are deposition apparatuses such as a chemical vapor deposition (CVD) apparatus, and a plasma enhanced chemical vapor deposition (PECVD) apparatus.

A CVD apparatus may place a substrate (for example, a wafer) on a wafer supporter, for example, a susceptor in a deposition chamber as a process chamber and perform a desired process on the substrate. Specifically, the CVD apparatus may be configured to place the substrate on the wafer supporter in the deposition chamber as the process chamber, heat the substrate on the wafer supporter to a determined temperature, and supply a process gas to the substrate from a gas supply unit installed to face an upper surface of the substrate, thereby depositing a thin film at a fixed thickness on the substrate.

In a PECVD method, a thin film may be deposited through a chemical reaction of reaction gases by generating plasma in a reaction chamber, and various types of thin films may be deposited through the PECVD method. The film characteristics such as surface uniformity, surface roughness, thickness uniformity, and the like of the deposited thin film may affect characteristics of resultant semiconductor devices, and thus largely affect the yield and productivity of the semiconductor apparatuses.

For this, uniform film characteristics (for example, thin film thickness and resistivity) have to be obtained over the entire surface of a wafer by distributing the process gas uniformly to the wafer in a process chamber so as to generate plasma discharge uniformly.

### SUMMARY OF THE INVENTION

Embodiments are provided to a gas supply apparatus capable of improving a film characteristic by supplying a process gas uniformly to a wafer in a process chamber and a substrate processing apparatus including the same.

In an embodiment of the present disclosure, a gas supply apparatus which supplies a plurality of groups of process gas to a substrate processing apparatus of which a plurality of wafers are placed in the inside, the apparatus may include: a plurality of process gas supply units configured to supply the plurality of groups of process gas; and a process gas temporary reservoir including an inner space partitioned into a plurality of gas storage spaces isolated from each other, each of which configured to store one group of process gas supplied from one process gas supply unit.

In an embodiment of the present disclosure, a substrate processing apparatus may include: a process chamber including a processing space configured to perform a substrate processing process on a plurality of wafers in the inside thereof; and a gas supply apparatus including a plurality of process gas supply units configured to supply a plurality of groups of process gas; and a process gas temporary reservoir including an inner space partitioned into a plurality of gas storage spaces isolated from each other, each of which configured to store one group of process gas supplied from one process gas supply unit and simultaneously supply the one group of process gas to the plurality of wafers.

According to the substrate processing apparatus of an embodiment of the present disclosure, when a unit process is simultaneously performed on a plurality of wafers in a single chamber, a certain amount of gas may be stored in a process gas temporary reservoir and then a uniform amount of gas may be supplied simultaneously to the plurality of wafers uniformly. Accordingly, a good thin film characteristic may be obtained and thus device characteristic may be improved.

Further, a single process gas temporary reservoir may be divided into a plurality of gas storage spaces, each of which have a zigzag inner structure and store one group of process gas including several different gases. The purpose of the zigzag inner structure is to mix the several different gas of one group of process gas more uniform. And every group of process gases after mixing uniformly in the corresponding gas storage space may be simultaneously provided to the plurality of wafers. Accordingly, an apparatus configuration may be simplified and a dimension of the apparatus may be reduced, and thus productivity of the semiconductor apparatus may be improved.

These and other features, aspects, and embodiments are described below.

### BRIEF DESCRIPTION OF THE DRAWING FIGURES

The above and other aspects, features and advantages of the subject matter of the present disclosure will be more clearly understood from the following detailed description taken in conjunction with the accompanying drawings, in which:

FIG. 1 is a cross-sectional view illustrating a configuration of a substrate processing apparatus according to an embodiment of the present disclosure;

FIG. 2 is a plan view illustrating a structure of a substrate processing apparatus according to an embodiment of the present disclosure;

FIG. 3 is a perspective view illustrating a configuration of a gas supply apparatus in a substrate processing apparatus according to an embodiment of the present disclosure;

FIG. 4 is a cross-sectional perspective view illustrating a structure of a process gas temporary reservoir in a gas supply apparatus according to an embodiment of the present disclosure;

FIG. 5 is a cross-sectional view illustrating a structure of a process gas temporary reservoir in a gas supply apparatus according to an embodiment of the present disclosure;

FIG. 6 is a diagram explaining a method of simultaneously supplying a plurality of process gases to one or more wafers loaded into a process chamber using a gas supply apparatus according to an embodiment of the present disclosure; and

FIG. 7 is a cross-sectional view illustrating a structure of a process gas temporary reservoir in a gas supply apparatus according to an embodiment of the present disclosure

### DETAILED DESCRIPTION OF THE EXEMPLARY EMBODIMENTS

Hereinafter, exemplary embodiments of the disclosure will be described more fully with reference to the accompanying drawings, in which the exemplary embodiments of the disclosure are shown to understand a configuration and an effect of the disclosure. The disclosure may, however, be embodied and modified in many different forms and this is not intended to limit the techniques described in this document to specific embodiments, but should be understood to cover various modifications, equivalents, and/or alternatives to the embodiments of this document.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that the terms first, second, third, etc. may be used herein to describe various elements and/or components regardless of the order and/or importance, and these elements and/or components should not be limited by these terms. These terms are only used to distinguish one element or component. Thus, without departing from the scope in the document, a first element and/or component discussed below could be termed a second element and/or component, and vice versa.

Spatially relative terms, such as “beneath,” “below,” “lower,” “above,” “upper” and the like, may be used herein for ease of description to describe one element or a relationship between a feature and another element or feature as illustrated in the figures. For example, if the apparatus in the figures is turned over, elements described as “below” or “beneath” other elements or features would then be oriented “above” the other elements or features. Thus, for example, the term “below” can encompass both an orientation which is above as well as below.

In the drawings, the thicknesses and volumes of layers and regions may be exaggerated for clarity, and like numbers refer to like elements throughout the description of the figure.

Hereinafter, a substrate processing apparatus according to an embodiment of the present disclosure will be described in detail with reference to the accompany drawings.

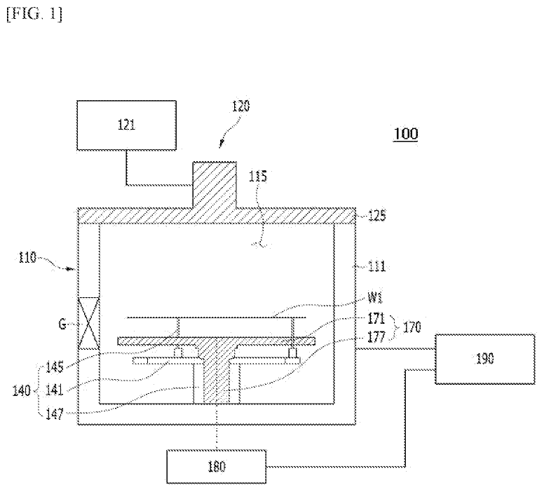

FIG. 1 is a cross-sectional view illustrating a configuration of a substrate processing apparatus 100 according to an embodiment of the present disclosure.

The substrate processing apparatus 100 according to an embodiment of the present disclosure may be a thin film deposition apparatus, for example, a plasma enhanced chemical vapor deposition (PECVD) apparatus. The substrate processing apparatus 100 may be configured to perform a unit process, for example, deposition of kinds of thin film like SiO₂, SiNₓ by PECVD method used in IC manufacture, on one or more wafers simultaneously.

Referring to FIG. 1, the substrate processing apparatus 100 according to an embodiment may include a process chamber 110 into which a wafer W1 is to be loaded. The process chamber 110 may be a thin film deposition chamber. The process chamber 110 may include a main body 111 and a processing space 115 in the inside of the main body 111.

In the process chamber 110, the main body 111 may have an opened upper portion and may be configured to perform the unit process on the wafer W1 in the processing space 115. The gas supply unit 120 to be described later may be disposed in the opened upper portion of the main body 111 and the main body 111 of the process chamber 110 may be configured to be sealed by the gas supply unit 120.

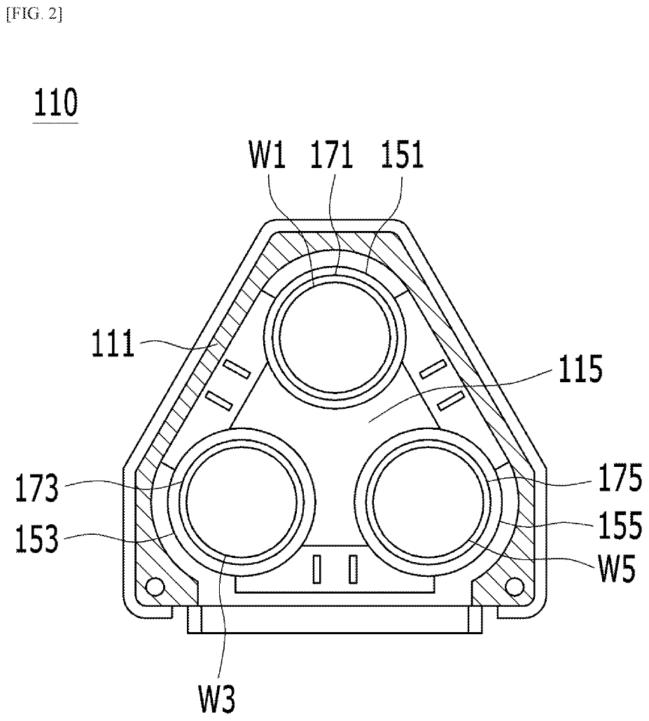

The processing space 115 may be a space provided in the inside of the main body 111 and may be configured to simultaneously perform the unit process, for example, deposition of thin film like SiO₂, SiNₓ by PECVD method used in IC manufacture, on a plurality of wafers W1, W3, and W5 loaded into the processing space 115 (see FIG. 2). It is understandable that the wafers loaded into the processing space 115 may be less, for example, one or two.

FIG. 2 is a plan view illustrating a configuration of the substrate processing apparatus 100 according to an embodiment of the present disclosure. FIG. 2 illustrates a plan structure of the process chamber 110 in the substrate processing apparatus 100. FIG. 1 illustrates only a space in which the unit process for one wafer, for example, a first wafer W1 among a plurality of wafers W1, W3, and W5 disposed in the processing space 115 of the process chamber 110 illustrated in FIG. 2 is to be performed.

Referring to FIG. 2, the process chamber 110 may be configured to simultaneously perform the unit process on the plurality of wafers W1, W3, and W5 in the processing space 115 of the main body 111. For example, the process chamber 110 may be configured to simultaneously perform the unit process on three wafers W1, W3, and W5.

A plurality of wafer placing units 151, 153, and 155 in which the plurality of wafers W1, W3, and W5 are to be placed may be provided in the processing space 115 of the process chamber 110. The main body 111 of the process chamber 110 may have a hexagonal structure so that three wafer placing units 151, 153, and 155 in which three wafers, for example, the first to third wafers W1, W3, and W5 are to be placed may be disposed in a triangular form.

In the embodiment, the plurality of wafers W1, W3, and W5 may include the first wafer W1, the second wafer W3, and the third wafer W5. The first to third wafers W1, W3, and W5 may be placed in the plurality of wafer placing units 151, 153, and 155 respectively, for example, a first wafer placing unit 151, a second wafer placing unit 153, and a third wafer placing unit 155.

A plurality of heaters 171, 173, and 175 to be described later may be disposed to respectively correspond to the plurality of wafers W1, W3, and W5 in the processing space 115 of the process chamber 110. The plurality of heaters 171, 173, and 175 may be disposed in the plurality of wafer placing units 151, 153, 155 respectively and may be configured to simultaneously heat the wafers W1, W3, and W5 placed in the plurality of wafer placing units 151, 153, and 155.

Specifically, the plurality of heaters 171, 173, and 175 may include a first heater 171 disposed in the first wafer placing unit 151 and configured to heat the first wafer W1, a second heater 173 disposed in the second wafer placing unit 153 and configured to heat the second wafer W3, and a third heater 175 disposed in the third wafer placing unit 155 and configured to heat the third wafer W5.

It is illustrated in FIG. 2 that the main body 111 of the process chamber 110 has the hexagonal structure that three wafers, for example, the first to third wafers W1, w3, and W5 are placed in the first to third wafer placing units 151, 153, and 155 in the embodiment, but this is not limited thereto. Any structure that one or more wafer placing units in which one or more wafers are placed are disposed and the unit process on the one or more wafers are simultaneously performed may be applied to the main body 111 of the process chamber 110.

Referring back to FIG. 1, in the substrate processing apparatus 100 according to an embodiment, the gas supply unit 120 may be disposed in the opened upper portion of the main body 111 of the process chamber 110 to face the wafer W1 placed in a wafer supporting unit 140. The gas supply unit 120 may be disposed to close the opened upper portion of the main body 111.

The gas supply unit 120 may include a gas supply part 121 configured to supply a process gas for thin film deposition provided from the outside of the main body 111 of the process chamber 110 and a gas spay part 125 configured to spray the process gas for thin film deposition supplied from the gas supply part 121 into the upper surface of the wafer W1 placed in the wafer supporting unit 140.

The gas spray part 125 of the gas supply unit 120 may be disposed in the opened upper portion of the main body 111 to face the wafer W1 placed in the wafer supporting unit 140 so that the processing space 115 of the main body 111 may be closed. Accordingly, the processing gas for thin film deposition may be sprayed into the processing space 115 of the main body 111 from the gas spray part 125 of the gas supply unit 120, so that a thin film may be deposited on the wafer W1.

The gas spray part 125 may serve as a support plate constituting an upper main body of the process chamber 110 and may include a shower head electrode assembly including a shower head. The electrode assembly may be configured to constitute an upper ceiling of the main body 111 of the process chamber 110 and may seal the main body 111 of the process chamber 110.

From the plan structure of the process chamber 110 illustrated in FIG. 2, the gas supply unit 120 may be disposed to entirely correspond to the processing space 115 of the process chamber 110. Specifically, the gas spray part 125 of the gas supply unit 120 may be disposed to close the opened processing space 115 of the process chamber 110 and may be configured to simultaneously supply the process gas to the first to third wafers W1, W3, and W5 disposed in the processing space 115. Accordingly, the thin film deposition process as the unit process may be collectively performed on the first to third wafers W1, W3, and W5 disposed in the processing space 115.

The process gas for thin film deposition supplied from the gas supply unit 120 may include various process gases such as a source gas, a carrier gas, and a purge gas. The gas supply unit 120 may be selected from among various types of gas supply apparatuses such as a shower head type, an injection type, and a nozzle type.

The substrate processing apparatus 100 according to an embodiment may further include the wafer supporting unit 140 disposed in the processing space 115 of the process chamber 110. FIG. 1 illustrates only a space of the processing space 115 of the process chamber 110 in which the unit process on the first wafer W1 is performed. The wafer supporting units 140 may be disposed in the process chamber 110 to correspond to a same number of wafers. For example, three wafer supporting units 140 may be disposed in the process chamber 110 to correspond to the first to third wafers W1, W3, and W5 disposed in the processing space 115. The three wafer supporting unit 140 may act as the wafer placing units 151, 153, and 155.

The wafer supporting unit 140 may include a wafer supporter 141, a plurality of pins 145 for supporting the wafer, and a support shaft 147 configured to support the wafer supporter 141. The wafer W1 placed on the pins 145 may be supported by the wafer supporter 141. The plurality of pins 145 may vertically pass through the heater 171, and be configured to be movable. The plurality of pins 145 may move the wafer W1 placed thereon up and down relative to the heater 171, so that the wafer W1 may be placed on the plurality of pins 145, as shown in FIG. 1, with a space between the wafer W1 and the heater 171 when the plurality of pins 145 move up and the wafer W1 may be placed on the heater 171 when the plurality of pins 145 move down. The unit process on the wafer W1 may be performed when the wafer W1 is placed on the heater 171.

In the embodiment, the wafer supporter 141 of the wafer supporting unit 140 may have an entirely flat circular shape so that the wafer W1 is horizontally placed on the plurality pins supported by the wafer supporter 141 and is disposed in parallel to the gas spray part 125 of gas supply unit 120, but this is not limited thereto, and may be variously modified.

For example, the support shaft 147 of the wafer supporting unit 140 may be configured to be fixed to the main body 111 of the process chamber 110. In this example, the support shaft 147 may be fixed to the main body 111 and may act to support the wafer supporter 141.

In another example, the support shaft 147 may be configured to be rotatable, and may support the wafer supporter 141 and rotate the wafer supporter 141 to rotate the wafer W1 placed in the wafer support pins 145. Besides, the support shaft 147 may also be configured to be movable, and may support the wafer supporter 141 and move the wafer supporter 141 to move the wafer W1 placed in the wafer support pins 145 up and down relative to the heater 171. In this example, although not shown in FIG. 1, a through hole, which the support shaft 147 of the wafer supporting unit 140, in which the wafer W1 is placed, is inserted there into and passes there through, may be formed in a portion of the main body 111, for example, a portion of a bottom of the main body 111.

The substrate processing apparatus 100 according to an embodiment may further include a heater unit 170 disposed in the processing space 115 of the process chamber 110. The heater unit 170 may be configured to heat the wafer W1.

As illustrated in FIG. 2, the heater unit 170 may include the plurality of heaters 171, 173, and 175 corresponding to the number of wafers to be loaded into the processing space 115 of the main body 111. The heater unit 170 may receive a power voltage from a power supply (not shown) outside the process chamber 110 to heat the plurality of heaters 171, 173, and 175.

For example, the heater unit 170 may include the first to third heaters 171, 173, 175 disposed in the wafer placing units 151, 153, and 155. The first to third heaters 171, 173, and 175 in the heater unit 170 may be configured to heat the first to third wafers W1, W3, and W5 placed in the wafer placing units 151, 153, and 155.

The heater unit 170 may include a support shaft 177 disposed to correspond to the first heater 171 and configured to support the first heater 171. Referring to FIG. 2, the support shafts 177 may be provided to the first to third heaters 171, 173, and 175, respectively, which are disposed to correspond to the first to third wafers W1, W3, and W5 placed in the first to third wafer placing units 151, 153, and 155, respectively.

For example, the support shaft 177 of the heater unit 170 may be configured to be fixed to the main body 111 of the process chamber 110. In this example, the support shaft 177 of the heater 171 may be fixed to the main body 111 and may act to support the heater 171.

In another example, the support shaft 177 for the heater 171 may be configured to be rotatable, and may support the heater 171 and rotate the heater 171. Besides, the support shaft 177 for the heater 171 may be configured to be movable, and may support the heater 171 and move the heater 171. In this example, although not shown in FIG. 1, a through hole, which the support shaft 177 of the heater unit 170 is inserted thereinto and passes therethrough, may be formed in a portion of the main body 111, for example, a portion of a bottom of the main body 111.

The substrate processing apparatus 100 according to an embodiment may further include a driving unit 180 disposed in the outside of the process chamber 110, for example, the main body 111 of the process chamber 110. The driving unit 180 may be coupled to any one of the wafer supporting unit 140 and the heater unit 170 and may drive the one of the wafer supporting unit 140 and the heater unit 170.

Although not shown in drawings, the driving unit 180 may include a motor and the like. For example, the driving unit 180 may include a direct drive (DD) motor. The driving unit 180 may rotate or move each wafer W1, W3, and W5 or each heater 171, 173, and 175 with the DD motor.

For example, when the support shaft 147 of the wafer supporting unit 140 is configured to be rotatable, the driving unit 180 may be coupled to the wafer supporting unit 140. In this case, the driving unit 180 may be configured to be coupled to the support shaft 147 of the wafer supporting unit 140 and to rotate the wafer W1 as illustrated in FIG. 1.

In this example, the support shaft 177 of the heater unit 170 may be configured to be fixed to the main body 111 of the process chamber 110. A portion of the support shaft 147 of the wafer supporting unit 140, which is coupled to the driving unit 180 through the through hole formed in the bottom of the main body 111, may be surrounded with a magnetic fluid seal member.

In another example, when the support shaft 177 of the heater unit 170 is configured to be rotatable, the driving unit 180 may be coupled to the heater unit 170. In this case, the driving unit 180 may be configured to be coupled to the support shaft 177 of the heater unit 170 and to rotate the heater 171 as illustrated in FIG. 1.

In this example, the support shaft 147 of the wafer supporting unit 140 may be configured to be fixed to the main body 111 of the process chamber 110. A portion of the support shaft 177 of the heater unit 170, which is coupled to the driving unit 180 through the through hole formed in the bottom of the main body 111, may be surrounded with a magnetic fluid seal member.

In further another example, when the support shaft 147 of the wafer supporting unit 140 and the support shaft 177 of the heater unit 170 are configured to be rotatable, the driving unit 180 may be coupled to the wafer supporting unit 140 and the heater unit 170. In this case, the driving unit 180 may be configured to be coupled to the support shaft 147 of the wafer supporting unit 140 and the support shaft 177 of the heater unit 170 and to simultaneously rotate the first wafer W1 and the heater 171.

In this example, the driving unit 180 may include a first driving unit coupled to the support shaft 147 of the wafer supporting unit 140 and configured to rotate the wafer W1, and a second driving unit, which is provided separately from the first driving unit, coupled to the support shaft 177 of the heater unit 170 and configured to rotate the heater 171. It's understandable that the first driving unit may include a motor configured to move the plurality of pins 141 by the support shaft 147 of the wafer supporting unit 140, similarly, the second driving unit may include a motor configured to move the heater 171 up and down by the support shaft 177 of the heater unit 170.

In this case, a portion of the support shaft 147 of the wafer supporting unit 140, which is coupled to the first driving unit through the through hole formed in the bottom of the main body 111, may be surrounded with a magnetic fluid seal member, and a portion of the support shaft 177 of the heater unit 170, which is coupled to the second driving unit through the through hole formed in the bottom of the main body 111, may be surrounded with a magnetic fluid seal member.

A gate G for carry-in/carry-out of the wafer W1 to/from the main body 111 may be provided in a portion of the process chamber 110. Although it is illustrated that the gate G is disposed in a side of the main body 111, but this is not limited thereto, and the gate G may be provided in any portion of the main body 111 for carry-in/out of the wafer W1 to/from the main body 111 of the process chamber 110.

Further, although not shown in drawings, an exhausting unit coupled to an external pump may be provided in a portion of the main body 111, for example, a portion of the bottom of the main body 111. The exhausting unit may allow the internal space 115 of the main body 111, as the processing space 115, to be in a vacuum state and may discharge gas generated after the substrate processing process.

The substrate processing apparatus 100 according to an embodiment may further include a controller 190 configured to control an overall operation of the process chamber 110. The controller 190 may control operations of the heater unit 170 provided within the main body 111, the gas supply unit 120, the driving unit 180, and the like, and set control parameters and the like for the substrate processing process, for example, a thin film deposition process, through interfacing with an operator Although not shown in drawings, the controller 190 may include a central processing unit (CPU), a memory, an input/output (I/O) interface, and the like. Further, the controller 190 may be configured to control rotation operations of the wafer W1 and the heater 171.

Hereinafter, a gas supply apparatus according to an embodiment corresponding to the gas supply part 121 of the gas supply unit 120 of FIG. 1 will be described in detail.

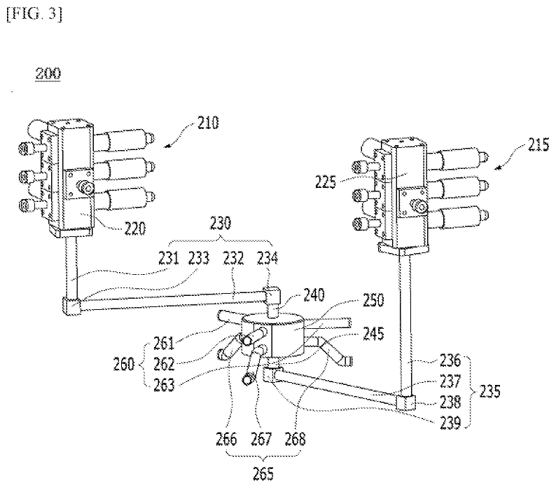

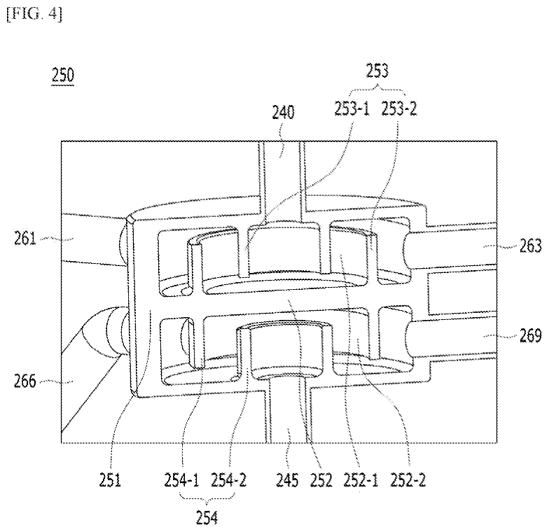

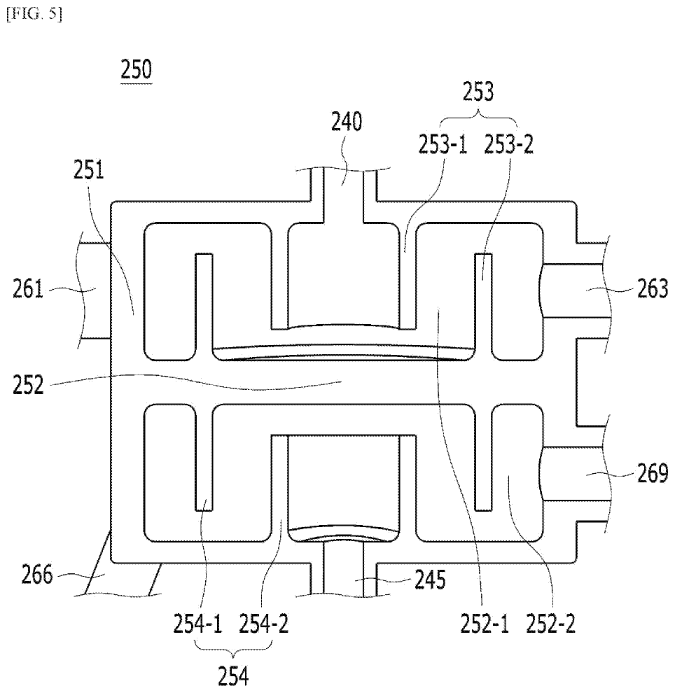

FIG. 3 is a perspective view illustrating a configuration of a gas supply apparatus 200 in a substrate processing apparatus according to an embodiment of the present disclosure. FIG. 4 is a cross-sectional perspective view illustrating a structure of a process gas temporary reservoir 250 in the gas supply apparatus 200 according to an embodiment of the present disclosure. FIG. 5 is a cross-sectional view illustrating a structure of the process gas temporary reservoir in the gas supply apparatus 200 according to an embodiment of the present disclosure.

The gas supply apparatus 200 according to an embodiment may be configured to supply a process gas for thin film deposition to the process chamber 110. The process gas for thin film deposition may be divided into a plurality of groups of process gas different from each other. And every group of process gas may include several different gases for forming one kind of thin film on a wafer surface. For example, the gas supply apparatus 200 may be configured to alternatively supply a first group of process gas such as mixed gases of TEOS, O₂ and Ar for forming SiO₂ thin film and a second group of process gas such as mixed gases of SiH₄, NH₃, Ar for forming Si₃N₄ film to the process chamber 110.

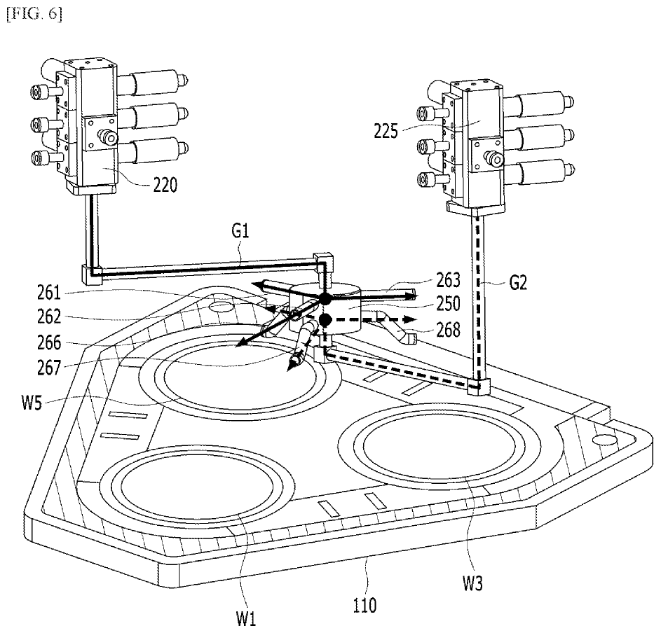

Referring to FIGS. 3 to 5, the gas supply apparatus 200 according to an embodiment may include a plurality of process gas supply units 210 and 215 configured to supply the plurality of groups of process gas. The plurality of process gas supply units 210 and 215 may include a plurality of process gas supply sources 220 and 225 configured to provide the plurality of groups of process gas. In other words, each process gas supply unit may include a process gas supply source configured to provide one group of process gas. The plurality of process gas supply sources 220 and 225 may include a first process gas supply source 220 configured to supply a first group of process gas (see G1 of FIG. 6) into the process chamber 110 and a second process gas supply source 225 configured to supply a second group of process gas (see G2 of FIG. 6), which is different from the first group of process gas G1, into the process chamber 110.

The gas supply apparatus 200 according to an embodiment may include a process gas temporary reservoir 250 configured to temporarily store the first group of process gas G1 provided from the first process gas supply source 220 and the second group of process gas G2 provided from the second process gas supply source 225.

The process gas temporary reservoir 250 may include a plurality of gas storage spaces (see 252-1 and 252-2 of FIG. 4) corresponding to the plurality groups of process gas. The plurality of gas storage spaces may be parallel with each other and stacked vertically, and each gas storage space may be configured to temporarily store one group of process gas and partially partitioned by a plurality of ring barriers to be described later to have a zigzag-shaped inner structure for making several different gases of one group of process gas mix more uniform. The plurality of gas storage spaces 252-1 and 252-2 may include a first gas storage space 252-1 configured to store the first group of process gas G1 and a second gas storage space 252-2 configured to store the second group of process gas G2.

Each gas storage space of the process gas temporary reservoir 250 may further include a gas inlet disposed on the center of it and configured to provide one group of process gas provided from the corresponding process gas supply source to the corresponding gas storage space of the process gas temporary reservoir. The process gas temporary reservoir 250 may further include a first process gas inlet 240 configured to inject the first group of process gas G1 provided from the first process gas supply source 220 to the first gas storage space 252-1 and a second process gas inlet 245 configured to inject the second group of process gas G2 provided from the second process gas supply source 225 to the second gas storage space 252-2.

Each gas storage space of the process gas temporary reservoir 250 may further include a plurality of gas outlets evenly disposed on the peripheral of it and configured to simultaneously discharge one group of process gas stored in it to the plurality of wafers W1, W2 and W3 in the process chamber 110, respectively. The process gas temporary reservoir 250 may further include a first process gas outlet 260 configured to discharge the first group of process gas G1 stored in the first gas storage space 252-1 to the outside (for example, the process chamber 110), and a second process gas outlet 265 configured to discharge the second group of process gas G2 stored in the second gas storage space 252-2 to the outside (for example, the process chamber 110).

The first process gas outlet 260 may include a plurality of gas outlets 261, 262, and 263 the number of which corresponding to the number of wafers to be simultaneously processed in the process chamber 110. The plurality of gas outlets 261 to 263 may simultaneously discharge the first group of process gas G1 stored in the first gas storage space 252-1 of the process gas temporary reservoir 250 to the first to third wafers W1, W3, and W5 of the process chamber 110, respectively.

The second process gas outlet 265 may include a plurality of gas outlets 266, 267, and 268 corresponding to the number of wafers to be simultaneously processed in the process chamber 110. The plurality of gas outlets 266 to 268 may simultaneously discharge the second group of process gas G2 stored in the second gas storage space 252-2 of the process gas temporary reservoir 250 to the first to third wafers W1, W3, and W5 of the process chamber 110, respectively.

Each gas supply unit may further include a process gas supply line configured to couple the process gas supply source of each gas supply unit to the corresponding gas storage space of the process gas temporary reservoir. The first and second process gas supply units 210 and 215 in the gas supply apparatus 200 according to an embodiment may further include a first process gas supply line 230 configured to supply the first group of process gas G1 and a second process gas supply line 235 configured to supply the second group of process gas G2, respectively.

The first process gas supply line 230 may be a gas supply line configured to supply the first group of process gas G1 provided from the first process gas supply source 220 to the first gas storage space 252-1 of the process gas temporary reservoir 250. The second process gas supply line 235 may be a gas supply line configured to supply the second group of process gas G2 provided from the second process gas supply source 225 to the second gas storage space 252-2 of the process gas temporary reservoir 250.

The first process gas supply line 230 may include supply lines 231 and 232 configured to supply the first group of process gas G1 provided from the first process gas supply source 220 to the first process gas inlet 240, a coupling part 233 configured to couple the supply lines 231 and 232, and a coupling part 234 configured to couple the supply line 232 and the first process gas inlet 240.

The second process gas supply line 235 may include supply lines 236 and 237 configured to supply the second group of process gas G2 provided from the second process gas supply source 225 to the second process gas inlet 245, a coupling part 238 configured to couple the supply lines 236 and 237, and a coupling part 239 configured to couple the supply line 237 and the second process gas inlet 245.

The gas supply apparatus 200 according to an embodiment may be largely divided into two parts, for example, a first process gas supply unit 210 and a second process gas supply unit 215 configured to provide the two groups of process gas G1 and G2 different from each other, respectively, and the process gas temporary reservoir 250 configured to temporarily store the two groups of process gases G1 and G2, respectively.

As described above, the first process gas supply unit 210, which is configured to supply the first group of process gas G1, may be configured of the first process gas supply source 220 and the first process gas supply line 230. The second process gas supply unit 215, which is configured to supply the second group of process gas G2, may be configured of the second process gas supply source 225 and the second process gas supply line 235.

Referring to FIGS. 4 and 5, the process gas temporary reservoir 250 may further include a main body 251 which defines an internal space and the internal space may be divided into a plurality of gas storage spaces which configured to store the plurality of groups of process gases, for example, the first group of process gases G1 and the second group of process gases G2. Each gas storage space may be partially partitioned to have a zigzag inner structure by a plurality of ring barriers which may include a plurality of first ring barriers (e.g. 253-1, 254-1) extending downwardly from the top of each gas storage space and a plurality of second ring barriers (e.g. 253-2, 254-2) extending upwardly from the bottom of each gas storage space, which alternatively and concentrically arranged with each other. The purpose of the zigzag inner structure of each gas storage space may be to make several different gases of one group of process gas mix more uniform.

The internal space defined through the main body 251 may be partitioned into an upper space and a lower space by a middle barrier 252 The upper space located in an upper side of the middle barrier 252 may act as the first gas storage space 252-1 configured to store the first group of process gas G1. The lower space located in a lower side of the middle barrier 252 may act as the second gas storage space 252-2 configured to store the second group of process gas G2.

The first gas storage space 252-1 may be partially partitioned through an upper ring barrier 253 to have a zigzag-shaped inner structure, and the second gas storage space 252-2 may be partially partitioned through a lower ring barrier 254 to have a zigzag inner structure. The first gas storage space 252-1 and the second gas storage space 252-2 may have a symmetrical structure with respect to the middle barrier 252.

Specifically, the first gas storage space 252-1 may be partially partitioned by a first upper ring barrier 253-1 extending downwardly from the main body 251 and a second upper ring barrier 253-2 extending upwardly from the middle barrier 252 to have a zigzag cross-sectional structure as illustrated in FIG. 5.

Further, the second gas storage space 252-2 may be partially partitioned by a first lower ring barrier 254-1 extending downwardly from the middle barrier 252 and a second lower ring barrier 254-2 extending upwardly from the main body 251 to have a zigzag cross-sectional structure as illustrated in FIG. 5.

The first gas storage space 252-1 may be configured to receive the first group of process gas G1 from the first process gas inlet 240, store the first group of process gas G1 by a certain amount, and then discharge the stored first group of process gas G1 through the first outlets 261 to 263.

The second gas storage space 252-2 may be configured to receive the second group of process gas G2 from the second process gas inlet 245, store the second group of process gas G2 by a certain amount, and then discharge the stored second group of process gas G2 through the second outlets 266 to 268.

FIG. 6 is a diagram explaining a method of simultaneously supplying the first group of process gas G1 or the second group of process gas G2 to three wafers W1, W3, and W5 loaded into one process chamber 110 using the gas supply apparatus 200 according to an embodiment of the present disclosure. It's worth to note that the plurality of gas outlets 261 to 263 and 266 to 268 may directly supply the plurality groups of process gas such as G1 and G2 to three wafers W1, W3, and W5 as shown in FIG. 6. But in other preferably embodiment, the plurality of gas outlets 261 to 263 and 266 to 268 may indirectly supply the plurality groups of process gas such as G1 and G2 to three wafers W1, W3, and W5. For example, the plurality of gas outlets 261 to 263 and 266 to 268 may connect with the gas spray part 125 of the gas supply unit 120 (not shown in FIG. 6) to supply the plurality groups of process gas to three wafers W1, W3, and W5.

Referring to FIG. 6 together with FIGS. 1 to 5, the first group of process gas G1 may be provided from the first process gas supply source 220 to the first process gas inlet 240 via the first process gas supply line 230 and then stored in the first gas storage space 252-1 of the process gas temporary reservoir 250.

When the certain amount of first group of process gas G1 is stored in the first gas storage space 252-1, the first group of process gas G1 may be simultaneously provided to the wafers W1, W3, and W5 placed in the wafer placing units 151, 153, and 155 in the process chamber 110 through the plurality of first outlets 261 to 263.

The second group of process gas G2 may be provided from the second process gas supply source 225 to the second process gas inlet 245 via the second process gas supply line 235 and then stored in the second gas storage space 252-2 of the process gas temporary reservoir 250.

When the certain amount of second group of process gas G2 is stored in the second gas storage space 252-2, the second group of process gas G2 may be simultaneously provided to the wafers W1, W3, and W5 placed in the wafer placing units 151, 153, and 155 in the process chamber 110 through the plurality of first outlets 266 to 268.

Specifically, the first process group of gas G1 discharged through the outlet 261 of the plurality of first outlets 261, 262, and 263 may be discharged toward the first wafer W1, the first group of process gas G1 discharged through the outlet 262 of the plurality of first outlets 261, 262, and 263 may be discharged toward the second wafer W3, and the first group of process gas G1 discharged through the outlet 263 of the plurality of first outlets 261, 262, and 263 may be discharged toward the third wafer W5. At this time, the first group of process gas G1 may be simultaneously provided to the first to third wafers W1, W3, and W5.

Further, the second group of process gas G2 discharged through the outlet 266 of the plurality of second outlets 266, 267, and 268 may be discharged toward the first wafer W1, the second group of process gas G2 discharged through the outlet 267 of the plurality of second outlets 266, 267, and 268 may be discharged toward the second wafer W3, and the second group of process gas G1 discharged through the outlet 268 of the plurality of second outlets 266, 267, and 268 may be discharged toward the third wafer W5. At this time, the second group of process gas G2 may be simultaneously provided to the first to third wafers W1, W3, and W5.

The first group of process gas G1 and the second group process gas G2 may be discharged alternatively toward the first to third wafers W1, W3, and W5 during the process of thin film deposition. As described above, the gas flow rout of each group of process gas may be independent in the gas supply apparatus 200, so the purge operation would be performed only for the process chamber 100 and not need to be performed for the gas supply apparatus 200 when switching from one group of process gas to another group of process gas, which may make the purge time for the processing apparatus 100 be shorten. Of course, the purge operation may be performed both for the process chamber 100 and the gas supply apparatus 200 according to process requirements of thin film deposition.

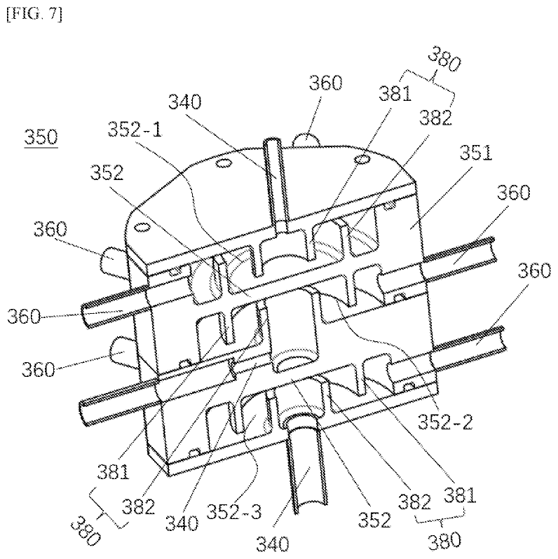

In the above description, the gas process gas temporary reservoir 250 may include two gas storage spaces 252-1 and 252-2 as shown in the FIG. 4. In other embodiments, the number of the plurality of gas storage spaces of the process gas temporary reservoir 250 may be three, four, five and so on, which may be determined according to the number of types of thin film formed on the wafer. For example, the gas process gas temporary reservoir 350 may include a main body 351 which defines an internal space, and the internal space may be divided into three gas storage spaces 352-1, 352-2 and 352-3 by two middle barriers 352 in parallel as shown in the FIG. 7. Each of the three gas storage spaces 352-1, 352-2 and 352-3 may include a gas inlet 340 disposed on the center of it, a plurality of gas outlets 360 disposed on the peripheral of it and a zigzag inner structure partially partitioned by a plurality of ring barriers 380. The plurality of ring barriers 380 of each gas storage space may include a plurality of first ring barrier 381 extending downwardly from the top of each gas storage space and a plurality of second ring barrier 382 extending upwardly from the bottom of each gas storage space, which alternatively and concentrically arranged with each other.

When the substrate processing apparatus 100 according to an embodiment is configured as a PECVD apparatus, any one of the wafer supporter 141 of the wafer supporting unit 140 and the gas spray part 125 of the gas supply unit 120 may serve as a first electrode, and the other one of the wafer supporter 141 of the wafer supporting unit 140 and the gas spray part 125 of the gas supply unit 120 may serve as a second electrode.

In this example, the substrate processing apparatus 100 according to an embodiment may further include an impedance matching unit (not shown). The impedance matching unit may be configured to provide power of a set frequency bandwidth as a plasma power source and prevent reflection loss due to reflection of high frequency power from the main body 111 by matching an output impedance of the plasma power and a load impedance in the main body 111.

It is illustrated in FIGS. 1 and 2 that the substrate processing apparatus 100 includes the first to third wafer placing units 151, 153, and 155, in which the first to third wafers W1, W3, and W5 are placed, and the first to third heaters 171, 173, and 175 disposed in the first to third wafer placing units 151, 153, and 155 and configured to heat the first to third wafers W1, W3, and W5, and simultaneously performs the unit process on three wafers W1, W3, and W5 in the processing space 115 within the main body 111 of the process chamber 110, in the embodiment. However, this is not limited thereto, and any structure that a plurality of wafers are loaded into the processing space 115 of the main body 111 and the unit process on the plurality of wafers are simultaneously performed may be available.

The above-described substrate processing apparatus according to the embodiment may be applied to other deposition apparatuses, for example, an atomic layer deposition (ALD) apparatus and the like, other than the PECVD apparatus. Further, the substrate processing apparatus according to the embodiment may be applied to any apparatus which may transfer a plurality of wafers in a single process chamber using a wafer transfer unit and then collectively perform a unit process on the plurality of wafers at once.

The foregoing exemplary embodiments and advantages are merely exemplary and are not to be construed as limiting the present invention. The present teaching can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed I

1. A gas supply apparatus which supplies a plurality of groups of process gas to a substrate processing apparatus of which a plurality of wafers are placed in the inside, the apparatus comprising:
a plurality of process gas supply units configured to supply the plurality of groups of process gas;
a process gas temporary reservoir including an inner space partitioned into a plurality of gas storage spaces isolated from each other, each of which configured to store one group of process gas supplied from one process gas supply unit and simultaneously supply the one group of process gas to the plurality of wafers.

2. The gas supply apparatus as claimed in claim 1, wherein each gas storage space is partially partitioned by a plurality of ring barriers to have a zigzag inner structure.

3. The gas supply apparatus as claimed in claim 2, wherein the plurality of ring barriers of each gas storage space includes a plurality of first ring barriers extending downwardly from a top of each gas storage space and a plurality of second ring barriers extending upwardly from a bottom of each gas storage space, the first ring barriers and the second ring barriers being alternatively and concentrically arranged with each other.

4. The gas supply apparatus as claimed in claim 1, wherein each gas supply unit includes:
a process gas supply source configured to provide one group of process gas;
a process gas supply line configured to couple the process gas supply source of each gas supply unit to a corresponding gas storage space of the process gas temporary reservoir.

5. The gas supply apparatus as claimed in claim of 4, wherein each gas storage space of the process gas temporary reservoir includes a gas inlet configured to couple the process gas supply line of each gas supply unit to the corresponding gas storage space of the process gas temporary reservoir.

6. The gas supply apparatus as claimed in claim of 5, wherein the gas inlet of each gas storage space is disposed on a center of the each gas storage space.

7. The gas supply apparatus as claimed in claim of 4, wherein each gas storage space of the process gas temporary reservoir includes a plurality of gas outlets configured to simultaneously provide one group of process gas stored in the each gas storage space to the plurality of wafers, respectively.

8. The gas supply apparatus as claimed in claim of 7, wherein the plurality of gas inlets of each gas storage space is evenly disposed on the peripheral of the each gas storage space.

9. A substrate processing apparatus comprising:
a process chamber including a processing space configured to perform a substrate processing process on a plurality of wafers in the inside thereof, and
a gas supply apparatus including a plurality of process gas supply units configured to supply a plurality of groups of process gas; and a process gas temporary reservoir including an inner space partitioned into a plurality of gas storage spaces isolated from each other, each of which configured to store one group of process gas supplied from one process gas supply unit and simultaneously supply the one group of process gas to the plurality of wafers.

10. The substrate processing apparatus as claimed in claim 9, wherein each gas storage space is partially partitioned by a plurality of ring barriers to have a zigzag inner structure.

11. The substrate processing apparatus as claimed in claim 10, wherein the plurality of ring barriers of each gas storage space includes a plurality of first ring barriers extending downwardly from a top of each gas storage space and a plurality of second ring barriers extending upwardly from a bottom of each gas storage space, the first ring barriers and the second ring barriers being alternatively and concentrically arranged with each other.

12. The substrate processing apparatus as claimed in claim 9, wherein each gas supply unit includes:
a process gas supply source configured to provide one group of process gas;
a process gas supply line configured to couple the process gas supply source of each gas supply unit to a corresponding gas storage space of the process gas temporary reservoir.

13. The substrate processing apparatus as claimed in claim 12, wherein each gas storage space of the process gas temporary reservoir includes a gas inlet configured to couple the process gas supply line of each gas supply unit to the corresponding gas storage space of the process gas temporary reservoir.

14. The substrate processing apparatus as claimed in claim 13, wherein the gas inlet of each gas storage space is disposed on a center of the each gas storage space.

15. The substrate processing apparatus as claimed in claim 12, wherein each gas storage space of the process gas temporary reservoir includes a plurality of gas outlets configured to simultaneously provide one group of process gas stored in the each gas storage space to the plurality of wafers, respectively.

16. The substrate processing apparatus as claimed in claim 15, wherein the plurality of gas inlets of each gas storage space is evenly disposed on the peripheral of the each gas storage space.

17. The substrate processing apparatus as claimed in claim 9, wherein the substrate processing process is a thin film deposition process performed in a plasma enhanced chemical vapor deposition (PECVD) apparatus.
